(19) United States
(12) Patent Application Publication
(10) Pub. No.: US 2024/0324404 A1
(43) Pub. Date: Sep. 26, 2024

(54) DISPLAY DEVICE

(71) Applicant: Samsung Display Co., Ltd., Yongin-si (KR)

(72) Inventors: DAEWOO LEE, Yongin-si (KR); Minhee PARK, Yongin-si (KR); KYUNGHOON CHAE, Yongin-si (KR); SOYEON JOO, Yongin-si (KR); HYEON DEUK HWANG, Yongin-si (KR)

(21) Appl. No.: 18/613,123

(22) Filed: Mar. 22, 2024

(30) Foreign Application Priority Data
Mar. 24, 2023 (KR) 10-2023-0038411

(51) Int. Cl. H10K 59/80; H10K 102/00

(52) U.S. Cl. CPC H10K 59/8721; H10K 59/872; H10K 2102/331

(57) ABSTRACT

A display device includes: a display module including a first flat portion, a second flat portion facing the first flat portion, and a bending portion disposed between the first flat portion and the second flat portion and having a predetermined radius of curvature; a driving circuit unit disposed on the second flat portion; a bending protection layer disposed on the bending portion, and not overlapping the first flat portion and the second flat portion; a cover film disposed on the second flat portion, and covering the driving circuit unit; and a resin layer including a first resin flat portion disposed on at least a portion of the first flat portion, a second resin flat portion disposed on the second flat portion and covering the cover film, and a resin bending portion disposed on the bending portion and covering the bending protection layer.

This application claims priority to Korean Patent Application No. 10-2023-0038411, filed on Mar. 24, 2023, and all the benefits accruing therefrom under 35 U.S.C. § 119, the content of which in its entirety is herein incorporated by reference.

### BACKGROUND

The present disclosure herein relates to a display device, and more particularly, to a display device including a resin layer disposed on a bending portion.

Various display devices have been made thin, small, and lightweight. Accordingly, various studies are being conducted for mounting driving elements for displaying an image on a display device in a limited region of the display device.

The display device may be provided in a form in which driving circuit units for displaying images are directly mounted on a display panel. The display panel or the driving circuit unit, however, has a risk of breakage, such as cracking if it is repeatedly bent or coupled in a bent state with other components.

### SUMMARY

The present disclosure provides a display panel having a bending portion with improved durability and a driving circuit unit with improved durability.

An embodiment of the invention provides a display device including: a display module having a first flat portion, a second flat portion facing the first flat portion, and a bending portion disposed between the first flat portion and the second flat portion and having a predetermined radius of curvature; a driving circuit unit disposed on the second flat portion; a bending protection layer disposed on the bending portion, and not overlapping the first flat portion and the second flat portion; a cover film disposed on the second flat portion, and covering the driving circuit unit; and a resin layer including a first resin flat portion disposed on at least a portion of the first flat portion, a second resin flat portion disposed on the second flat portion and covering the cover film, and a resin bending portion disposed on the bending portion and covering the bending protection layer.

In an embodiment, a thickness of a part of the second resin flat portion not overlapping the driving circuit unit may be about 50 micrometers (μm) to about 1000 μm.

In an embodiment, a thickness of the resin bending portion may be greater than a thickness of the bending protection layer.

In an embodiment, the thickness of the resin bending portion may be about 150 μm to about 3000 μm.

In an embodiment, an electrical conductivity of the resin layer may be about 100 Siemens per square centimeter (S/cm²) or greater.

In an embodiment, the resin layer may include at least one of an acrylic resin, an epoxy-based resin, a silicon-based resin, a pyrrole-based resin, a furan-based resin, a thiophene-based resin, an aniline-based resin, or poly(3,4-ethylenedioxythiophene (PEDOT).

In an embodiment, the resin layer may include a base portion, and metal particles dispersed inside the base portion, wherein the metal particles may include at least one of copper (Cu) or aluminium (Al).

In an embodiment, the resin layer may include about 0.01 volume percent (vol %) to about 85.00 vol % of the metal particles based on a total volume of the resin layer.

In an embodiment, a shear modulus of the resin layer at 25° C. may be about 1 megapascal (MPa) to about 1000 MPa.

In an embodiment, the display device may further include a window disposed on the display module, wherein the window may be directly disposed on the first resin flat portion.

In an embodiment, the resin layer may be provided as a single layer.

In an embodiment, the cover film may include: a first cover insulation layer, a middle layer disposed on the first cover insulation layer, and a second cover insulation layer disposed on the middle layer.

In an embodiment, the driving circuit unit may be directly disposed on the second flat portion.

In an embodiment, the display device may further include a cover panel disposed between the first flat portion and the second flat portion, and may further include a panel inner protection layer filling a space defined by an exposed part of the cover panel, the first flat portion, the second flat portion, and the bending portion.

In an embodiment of the invention, a display device includes: a display module including a first flat portion, a second flat portion facing the first flat portion, and a bending portion disposed between the first flat portion and the second flat portion and having a predetermined radius of curvature; a window disposed on the first flat portion; an adhesive layer disposed between the display module and the window; a driving circuit unit disposed on the second flat portion, and a resin layer including a first resin flat portion filling a groove defined by the first flat portion, the window, and an exposed part of the adhesive layer, a second resin flat portion disposed on the second flat portion and covering the driving circuit unit, and a resin bending portion disposed on the bending portion.

In an embodiment, the resin layer may be provided as a single layer.

In an embodiment, the window may be directly disposed on the first resin flat portion.

In an embodiment, an electrical conductivity of the resin layer may be about 100 S/cm² or greater.

In an embodiment, the resin layer may include a base portion, and metal particles dispersed inside the base portion, wherein the metal particles may include at least one of Cu or Al.

In an embodiment, a shear modulus of the resin layer at 25° C. may be about 1 MPa to about 1000 MPa.

### BRIEF DESCRIPTION OF THE FIGURES

The accompanying drawings are included to provide a further understanding of the invention, and are incorporated in and constitute a part of this specification. The drawings illustrate exemplary embodiments of the invention and, together with the description, serve to explain principles of the invention. In the drawings:

FIG. 1A is a perspective view of an electronic device according to an embodiment of the invention;

FIG. 1B is an exploded perspective view illustrating some components of an electronic device according to an embodiment of the invention;

FIG. 2 is a cross-sectional view of an electronic device according to an embodiment of the invention;

FIG. 3A is a plan view of a display panel according to an embodiment of the invention;

FIG. 3B is a plan view of an input sensing layer according to an embodiment of the invention;

FIG. 4 is a cross-sectional view showing a portion of a display device of an embodiment of the invention;

FIG. 5 is a view of an enlarged resin layer of an embodiment of the invention;

FIG. 6 is a cross-sectional view showing a portion of a display device of another embodiment of the invention;

FIG. 7A is a cross-sectional view showing a portion of a display device of still another embodiment of the invention;

FIG. 7B is a view showing a cover film of an embodiment of the invention in detail;

FIG. 8 is a cross-sectional view showing a portion of a display device of yet another embodiment of the invention;

FIG. 9 is a cross-sectional view showing a portion of a display device of another embodiment of the invention;

FIG. 10A is a view showing a preliminary display device before bending;

FIG. 10B is a view showing a preliminary display device after bending;

FIG. 11 is a view schematically showing a process of applying a preliminary resin layer on a preliminary display device after bending; and

FIG. 12 is a view schematically showing a step of irradiating a preliminary resin layer with light.

### DETAILED DESCRIPTION

The invention may be modified in many alternate forms, and thus specific embodiments will be exemplified in the drawings and described in detail. It should be understood, however, that it is not intended to limit the invention to the particular forms disclosed, but rather, is intended to cover all modifications, equivalents, and alternatives falling within the spirit and scope of the invention.

In the present disclosure, when an element (or a region, a layer, a portion, etc.) is referred to as being “on,” “connected to,” or “coupled to” another element, it means that the element may be directly disposed on/connected to/coupled to the other element, or that a third element may be disposed therebetween.

Like reference numerals refer to like elements. Also, in the drawings, the thickness, the ratio, and the dimensions of elements are exaggerated for an effective description of technical contents. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” The term “and/or” includes any and all combinations of one or more of which associated elements may define.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the present invention. The terms of a singular form may include plural forms unless the context clearly indicates otherwise.

In addition, terms such as “below,” “lower,” “above,” “upper,” and the like are used to describe the relationship of the elements shown in the drawings. The terms are used as a relative concept and are described with reference to the direction indicated in the drawings.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present invention pertains. It is also to be understood that terms such as terms defined in commonly used dictionaries should be interpreted as having meanings consistent with the meanings in the context of the related art, and should not be interpreted in too ideal a sense or an overly formal sense unless explicitly defined herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within +30%, 20%, 10% or 5% of the stated value. Hereinafter, a display device according to an embodiment of the invention will be described with reference to the accompanying drawings.

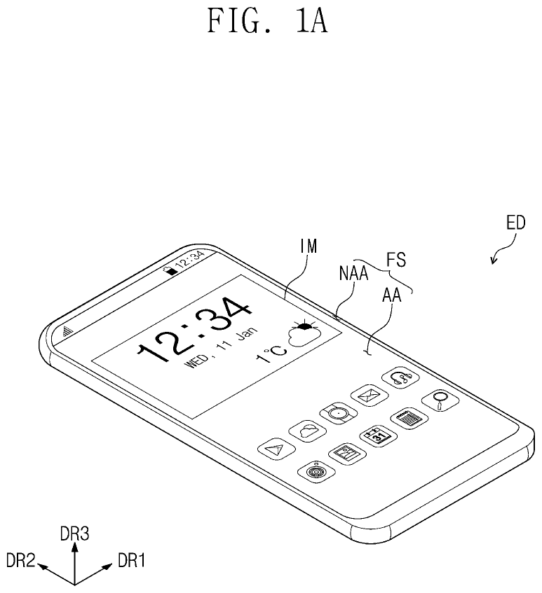

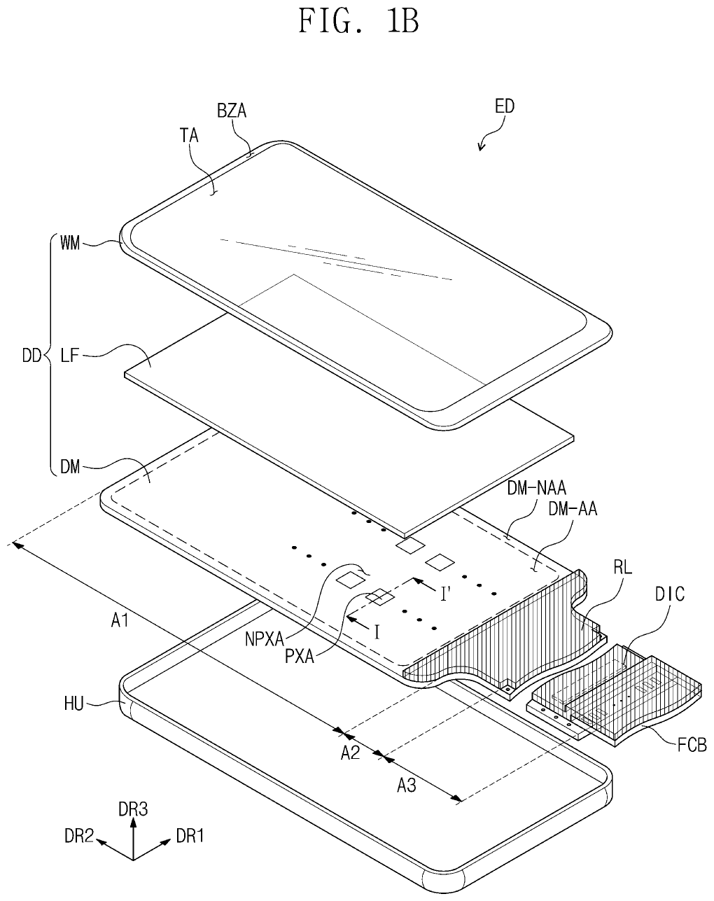

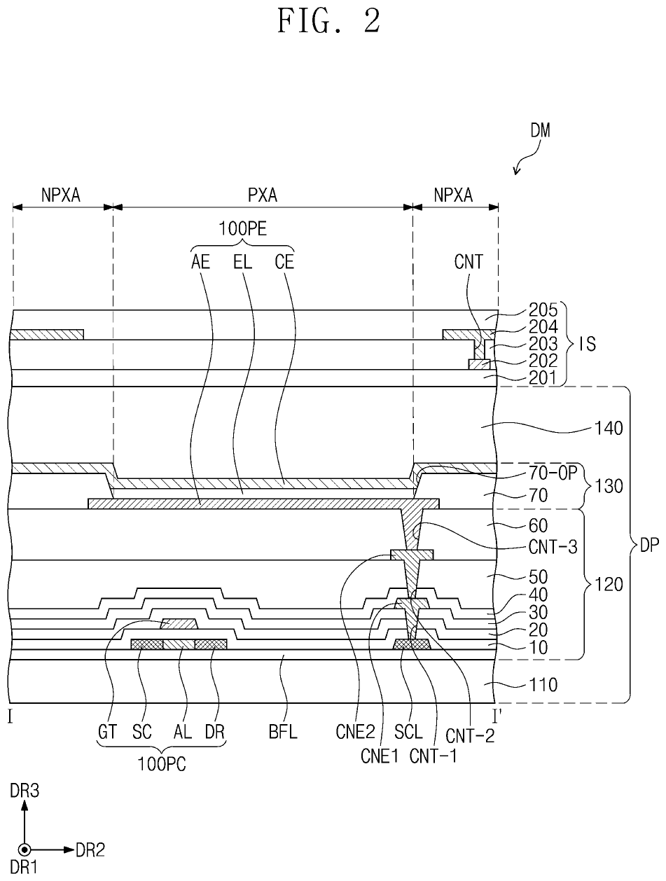

FIG. 1A is a perspective view of an electronic device according to an embodiment of the invention. FIG. 1B is an exploded perspective view illustrating some components of an electronic device according to an embodiment of the invention. FIG. 2 is a cross-sectional view of an electronic device according to an embodiment of the invention. FIG. 2 may correspond to a cross-sectional view of an electronic device of an embodiment taken along line I-I′ illustrated in FIG. 1B.

Referring to FIG. 1A, an electronic device ED of an embodiment may include a display surface FS parallel to a plane defined by a first direction DR1 and a second direction DR2. The display surface FS may display an image IM in a third direction DR3 perpendicular to the first direction DR1 and the second direction DR2. The display surface FS which displays the image IM may be defined as a front surface. The image IM may include both a moving image and a still image.

In the present embodiment, with respect to the third direction DR3 in which the image IM is displayed, a front surface (or an upper surface) and a back surface (or a lower surface) of each member are defined. The front surface and the back surface oppose each other in the third direction DR3, and a normal direction of each of the front surface and the back surface may be parallel to the third direction DR3.

A separation distance between the front surface and the back surface in the third direction DR3 may correspond to a thickness of the electronic device ED in the third direction DR3. Directions indicated by the first to third directions DR1, DR2, and DR3 are a relative concept, and may be converted into other directions.

The electronic device ED may sense an external input applied from the outside. The external input may include various forms of inputs provided from the outside of the electronic device ED. In an embodiment, for example, the external input may include not only a contact by a part of a user's body, such as a hand, but also an external input applied in close proximity, or adjacent to the electronic device ED at a predetermined distance (for example, hovering). Also, the external input may have various forms, such as force, pressure, temperature, light, and the like.

The front surface of the electronic device ED may be divided into a display region AA and a non-display region NAA. The display region AA may be a region in which the image IM is displayed. The display region AA is illustrated as having vertices in a round quadrangular shape. However, this is exemplarily illustrated, and the display region AA may have various shapes, and is not limited to any one embodiment.

The non-display region NAA is adjacent to the display region AA. The non-display region NAA may have a predetermined color. The non-display region NAA may surround the display region AA. Accordingly, the shape of the display region AA may be substantially defined by the non-display region NAA. However, this is exemplarily illustrated, and the non-display region NAA may be disposed adjacent to only one side of the display region AA, or may be omitted. The electronic device ED according to an embodiment of the invention may include various embodiments, and is not limited to any one embodiment.

Referring to FIG. 1B, the electronic device ED may include a display device DD and a housing HU. The display device DD may include a window WM, an optical film LF, and a display module DM. The window WM and the housing HU are coupled to each other to configure the appearance of the display device EA.

The window WM may be made of a transparent material capable of emitting an image. In an embodiment, for example, the window WM may be composed of glass, sapphire, plastic, or the like. The window WM may include a transmission area TA and a bezel area BZA. The transmission area TA may be overlapped with at least a portion of the active area DM-AA of the display module DM. The transmission area TA may be an optically transparent area. Images IM (FIG. 1) may be provided through the transmission area TA to a user.

The bezel area BZA may be an area having relatively low light transmittance in contrast to the transmission area TA. The bezel area BZA may define the shape of the transmission area TA. The bezel area BZA may be adjacent to the transmission area TA and surround the transmission area TA.

The bezel area BZA may have certain color. The bezel area BZA may cover the surrounding area DM-NAA of the display module DM and block the surrounding area DM-NAA from being recognized by the outside. However, an embodiment of the invention is not limited thereto, and the bezel area BZA may be disposed adjacent to only one side of the transmission area TA, or at least a portion thereof may be omitted in another embodiment.

The optical film LF may be disposed in a lower portion of the window WM. The window WM reduces the reflectance of external light incident from an upper side of the window WM. The optical film LF may include a retarder and a polarizer. The retarder may be of a film type or a liquid crystal coating type, and may include a W2 retarder and/or a N4 retarder. The polarizer may also be of a film type or a liquid crystal coating type. The film-type polarizer may include a stretchable synthetic resin film, and the liquid crystal coating-type polarizer may include liquid crystals arranged in a predetermined arrangement. The retarder and the polarizer may be implemented as a single polarizing film. The optical film LF may further include a protection film disposed either in an upper portion or a lower portion of the polarizing film.

The display module DM may be disposed in a lower portion of the optical film LF. Between the display module DM and the window WM, a functional layer which performs another function other than the optical film LF, for example, a protection layer, may be further disposed.

The display module DM may be defined as an active region DM-AA and a peripheral region DM-NAA. The active region DM-AA may be defined as a region which emits an image provided from the display module DM. The peripheral region DM-NAA is adjacent to the active region DM-AA. For example, the peripheral region DM-NAA may surround the active region DM-AA. However, this is exemplarily illustrated, and the peripheral region DM-NAA may be defined in various shapes, and is not limited to any one embodiment. According to an embodiment, the active region DM-AA of the display module DM may correspond to at least a portion of the display region AA.

The active region DM-AA may be separated into a pixel region PXA and a non-pixel region NPXA. A plurality of pixel regions PXA may disposed spaced apart from each other. The non-pixel region NPXA may be in a shape of surrounding the pixel region PXA.

According to the invention, the display module DM may include a first region A1, a second region A2, and a third region A3, which are arranged in the second direction DR2. The first region A1 may include the active region DM-AA. In the present disclosure, a region of the first region A1 except for the active region DM-AA, the second region A2, and the third region A3 may correspond to the peripheral region DM-NAA.

The third region A3 may have a driving circuit unit DIC mounted thereon, and include pads PD disposed adjacent to an end thereof. A flexible circuit board FCB may be disposed on the pads PD of the third region A3, and be electrically connected to the display module DM. A detailed description thereof will be given later.

According to the invention, the display module DM may include a resin layer RL disposed thereon. The resin layer RL may cover the flexible circuit board FCB. In addition, the resin layer RL may be disposed on the display module DM, and cover at least a portion of the third region A3 and the entire region of the second region A2. At this time, the resin layer RL may cover the entire driving circuit unit DIC mounted on the third region A3. According to an embodiment, as illustrated in FIG. 1B, the resin layer RL may be continuously extended from the flexible circuit board FCB to the second region A2 of the display module DM.

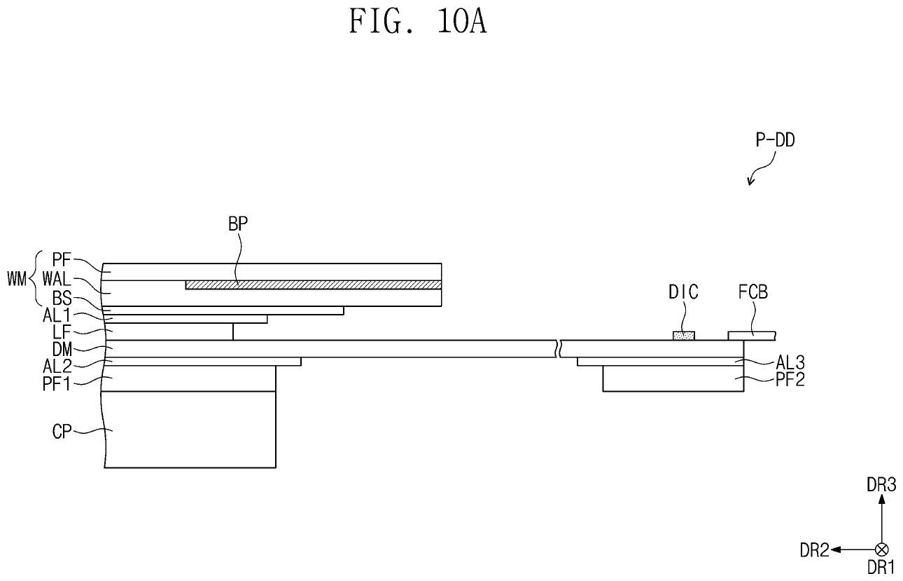

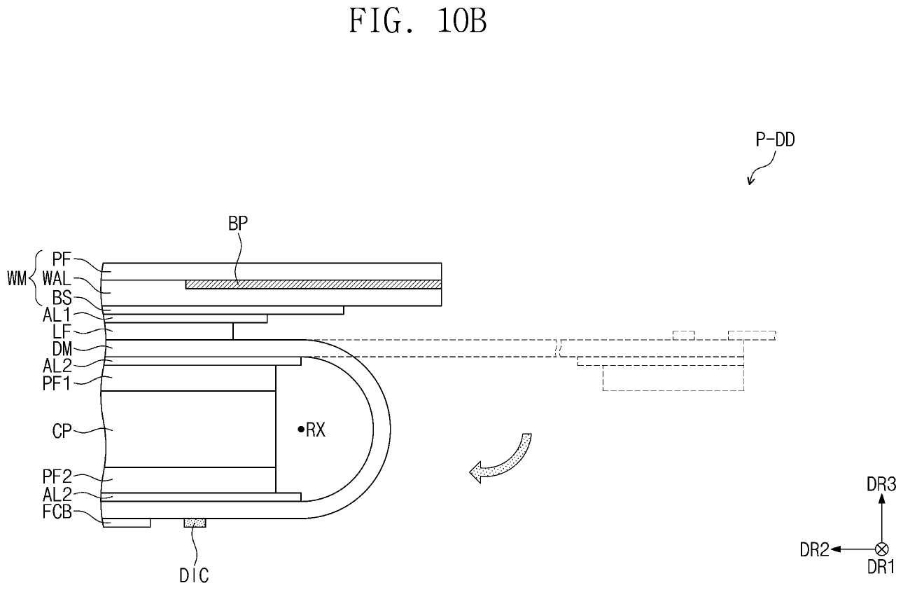

According to the invention, the second region A2 of the display module DM may be bent such that the third region A3 faces the back surface of the display module DM. At this time, the driving circuit unit DIC and the flexible circuit board FCB may be disposed in a lower portion of the first region A1. The resin layer RL may be disposed on the bent display module DM. The process of forming the resin layer RL will be described in more detail with reference to FIG. 10A to FIG. 12.

The display module DM may include a display panel DP (see FIG. 2) and an input sensing layer IS (see FIG. 2) disposed on the display panel DP (see FIG. 2). The display panel DP (see FIG. 2) generates an image, and the input sensing layer IS (see FIG. 2) obtains coordinate information of an external input (for example, a touch event). Therefore, the display module DM displays an image in response to an electrical signal, and may transmit/receive information on an external input.

The display panel DP (see FIG. 2) may be a component which substantially generates an image. The display panel DP (see FIG. 2) may be any one of an organic light emitting display panel, a quantum-dot display panel, and an inorganic light emitting display panel, but is not particularly limited thereto.

The housing HU is coupled to the window WM. The housing HU is coupled to the window WM and provides a predetermined internal space. The housing HU includes a plurality of sidewall portions, and the plurality of sidewall portions of the housing HU and the window WM may provide the predetermined internal space. The display module DM may be accommodated in the internal space.

The housing HU may include a material having relatively high rigidity. In an embodiment, for example, the housing HU may include glass, plastic, or a metal, or may include a plurality of frames and/or plates composed of a combination thereof. The housing HU may stably protect components of the display device EA accommodated in the internal space from an external impact.

Referring to FIG. 2, the display layer DP may include a base layer 110, a circuit element layer 120, a light emitting element layer 130, and an encapsulation layer 140. The base layer 110 may be a member which provides a base surface on which the circuit element layer 120 is disposed. The base layer 110 may be a glass substrate, a metal substrate, a polymer substrate, or the like. However, the embodiment of the invention is not limited thereto, and the base layer 110 may be an inorganic layer, an organic layer, or a composite material layer in another embodiment.

The base layer 110 may have a multi-layered structure. In an embodiment, for example, the base layer 110 may include a first synthetic resin layer, a silicon oxide(SiOₓ) layer disposed on the first synthetic resin layer, an amorphous silicon(a-Si) layer disposed on the silicon oxide layer, and a second synthetic resin layer disposed on the amorphous silicon layer. The silicon oxide layer and the amorphous silicon layer may be referred to as a base barrier layer.

Each of the first and second synthetic resin layers may include a polyimide-based resin. In addition, each of the first and second synthetic resin layers may include at least one of an acrylate-based resin, a methacrylate-based resin, a polyisoprene-based resin, a vinyl-based resin, an epoxy-based resin, a urethane-based resin, a cellulose-based resin, a siloxane-based resin, a polyamide-based resin, or a perylene-based resin. In the present disclosure, a “˜˜”-based resin means that a functional group of “˜˜” is included.

The circuit element layer 120 may be disposed above the base layer 110. The circuit element layer 120 may include an insulation layer, a semiconductor pattern, a conductive pattern, a signal line, and the like. The insulation layer, a semiconductor layer, and a conductive layer are formed above the base layer 110 by coating, deposition, or the like, and thereafter, the insulation layer, the semiconductor layer, and the conductive layer may be selectively patterned through performing a photolithography process a plurality of times. Thereafter, the semiconductor pattern, the conductive pattern, and the signal line which are included in the circuit element layer 120 may be formed.

At least one inorganic layer is disposed on an upper surface of the base layer 110. The inorganic layer may include at least one of an aluminum oxide, a titanium oxide, a silicon oxide, a silicon nitride, a silicon oxynitride, a zirconium oxide, or a hafnium oxide. The inorganic layer may include multiple layers. The multi-layered inorganic layers may configure a barrier layer and/or a buffer layer. In the present embodiment, the display panel DP is illustrated as including a buffer layer BFL.

The buffer layer BFL may improve the coupling force between the base layer 110 and the semiconductor pattern. The buffer layer BFL may include at least one of a silicon oxide, a silicon nitride, or a silicon oxynitride. In an embodiment, for example, the buffer layer BFL may include a structure in which a silicon oxide layer and a silicon nitride layer are alternately stacked.

The semiconductor pattern may be disposed on the buffer layer BFL. The semiconductor pattern may include polysilicon. However, the embodiment of the invention is not limited thereto, and the semiconductor pattern may include amorphous silicon, low-temperature polycrystalline silicon, or an oxide semiconductor in another embodiment.

FIG. 2 only illustrates some semiconductor patterns, and the semiconductor pattern may be further disposed in another region. The semiconductor pattern may be arranged according to a specific rule across pixels. The semiconductor pattern may have different electrical properties depending on whether or not the semiconductor pattern is doped. The semiconductor pattern may include a first region having a high conductivity rate and a second region having a low conductivity rate.

The first region may be doped with an N-type dopant or a P-type dopant. A P-type transistor may include a doped region doped with the P-type dopant, and an N-type transistor may include a doped region doped with the N-type dopant. The second region may be a non-doped region, or a region doped to a concentration lower than a doped concentration of the first region.

The first region may have a conductivity greater than a conductivity of the second region, and may substantially serve as an electrode or a signal line. The second region may substantially correspond to an active (or a channel) of a transistor. In other words, a portion of the semiconductor pattern may be an active of a transistor, another portion thereof may be a source or a drain of the transistor, and the other portion thereof may be a connection electrode or a connection signal line.

Each pixel may have an equivalent circuit including seven transistors, one capacitor, and a light emitting element, and the equivalent circuit diagram of a pixel may be modified in various forms. FIG. 2 exemplarily illustrates one transistor 100PC and a light emitting element 100PE included in a pixel.

A source SC, an active AL, and a drain DR of the transistor 100PC may be formed from the semiconductor pattern. The source SC and the drain DR may be extended in opposite directions from each other with respect to the active AL on a cross-section. FIG. 2 illustrates a portion of a connection signal line SCL formed from the semiconductor pattern. Although not separately illustrated, the connection signal line SCL may be connected to the drain DR of the transistor 100PC on a plane.

A first insulation layer 10 may be disposed on the buffer layer BFL. The first insulation layer 10 commonly overlaps a plurality of pixels, and may cover the semiconductor pattern. The first insulation layer 10 may be an inorganic layer and/or an organic layer, and may have a single-layered or multi-layered structure. The first insulation layer 10 may include at least one of an aluminum oxide, a titanium oxide, a silicon oxide, a silicon nitride, a silicon oxynitride, a zirconium oxide, or a hafnium oxide. In the present embodiment, the first insulation layer 10 may be a single-layered silicon oxide layer. Not only the first insulation layer 10 but also an insulation layer of the circuit element layer 120 to be described later may be an inorganic layer and/or an organic layer, and may have a single-layered structure or multi-layered structure. The inorganic layer may include at least one of the above-described materials, but is not limited thereto.

A gate GT of the transistor 100PC is disposed on the first insulation layer 10. The gate GT may be a portion of a metal pattern. The gate GT overlaps the active AL. In a process of doping the semiconductor pattern, the gate GT may function as a mask.

A second insulation layer 20 is disposed on the first insulation layer 10, and may cover the gate GT. The second insulation layer 20 may commonly overlap pixels. The second insulation layer 20 may be an inorganic layer and/or an organic layer, and may have a single-layered or multi-layered structure. The second insulation layer 20 may include at least one of a silicon oxide, a silicon nitride, or a silicon oxynitride. In the present embodiment, the second insulation layer 20 may have a multi-layered structure including a silicon oxide layer and a silicon nitride layer.

A third insulation layer 30 may be disposed on the second insulation layer 20. The third insulation layer 30 may have a single-layered or multi-layered structure. In an embodiment, for example, the third insulation layer 30 may have a multi-layered structure including a silicon oxide layer and a silicon nitride layer.

A first connection electrode CNE1 may be disposed on the third insulation layer 30. The first connection electrode CNE1 may be connected to the connection signal line SCL through a contact-hole CNT-1 passing through the first to third insulation layers 10, 20, and 30.

A fourth insulation layer 40 may be disposed on the third insulation layer 30. The fourth insulation layer 40 may be a single-layered silicon oxide layer. A fifth insulation layer 50 may be disposed on the fourth insulation layer 40. The fifth insulation layer 50 may be an organic layer.

A second connection electrode CNE2 may be disposed on the fifth insulation layer 50. The second connection electrode CNE2 may be connected to the first connection electrode CNE1 through a contact-hole CNT-2 passing through the fourth insulation layer 40 and the fifth insulation layer 50.

A sixth insulation layer 60 is disposed on the fifth insulation layer 50, and may cover the second connection electrode CNE2. The sixth insulation layer 60 may be an organic layer.

The light emitting element layer 130 may be disposed on the circuit element layer 120. The light emitting element layer 130 may include a light emitting element. In an embodiment, for example, the light emitting element layer 130 may include an organic light emitting material, a quantum dot, a quantum rod, a micro LED, or a nano LED. Hereinafter, the light emitting element 100PE is exemplarily described as being an organic light emitting element, but is not particularly limited thereto.

The light emitting element 100PE may include a first electrode AE, a light emitting layer EL, and a second electrode CE. The first electrode AE may be disposed on the sixth insulation layer 60. The first electrode AE may be connected to the second connection electrode CNE2 through a contact-hole CNT-3 passing through the sixth insulation layer 60.

A pixel definition film 70 is disposed on the sixth insulation layer 60, and may cover a portion of the first electrode AE. In the pixel definition film 70, an opening 70-OP is defined. The opening 70-OP of the pixel definition film 70 exposes at least a portion of the first electrode AE.

The active region DM-AA (see FIG. 1B) may include a pixel region PXA, and a non-pixel region NPXA adjacent to the pixel region PXA. The non-pixel region NPXA may surround the pixel region PXA. In the present embodiment, the pixel region PXA is defined to correspond to some regions of the first electrode AE exposed by the opening 70-OP.

The light emitting layer EL may be disposed on the first electrode AE. The light emitting layer EL may be disposed in a region corresponding to the opening 70-OP. That is, the light emitting layer EL may be separately disposed in each of the pixels. When the light emitting layer EL is separately disposed in each of the pixels, each of the light emitting layers EL may emit light of at least one of blue, red, or green colors. However, the embodiment of the invention is not limited thereto, and the light emitting layer EL may be connected to the pixels and commonly provided in another embodiment. In this case, the light emitting layer EL may provide blue light or white light.

The second electrode CE may be disposed on the light emitting layer EL. The second electrode CE may have a shape of a single body, and be commonly disposed in the plurality of pixels.

Although not illustrated, a hole control layer may be disposed between the first electrode AE and the light emitting layer EL. The hole control layer may be commonly disposed in the pixel region PXA and the non-pixel region NPXA. The hole control layer includes a hole transport layer, and may further include a hole injection layer. An electron control layer may be disposed between the light emitting layer EL and the second electrode CE. The electron control layer includes an electron transport layer, and may further include an electron injection layer. The hole control layer and the electron control layer may be commonly formed in the plurality of pixels using an open mask.

The encapsulation layer 140 may be disposed above the light emitting element layer 130. The encapsulation layer 140 may include an inorganic layer, an organic layer, and an inorganic layer sequentially stacked, but layers constituting the encapsulation layer 140 are not limited thereto.

The inorganic layers may protect the light emitting element layer 130 from moisture and oxygen, and the organic layer may protect the light emitting element layer 130 from foreign materials such as dust particles. The inorganic layers may include a silicon nitride layer, a silicon oxynitride layer, a silicon oxide layer, a titanium oxide layer, an aluminum oxide layer, or the like. The organic layer may include an acrylic organic layer, but is not limited thereto.

The input sensing layer IS may be disposed on the display panel DP through a continuous process. In this case, the input sensing layer IS may be described as being ‘directly disposed’ on the display panel DP. Being directly disposed may mean that a third element is not disposed between the input sensing layer IS and the display panel DP. That is, a separate adhesive member may not be disposed between the input sensing layer IS and the display panel DP.

Alternatively, the input sensing layer IS may be provided as a separate module and may be coupled to the display panel DP through an adhesive member. The adhesive member may include a typical adhesive or pressure-sensitive adhesive.

The input sensing layer IS may include a first sensing insulation layer 201, a first conductive layer 202, a second sensing insulation layer 203, a second conductive layer 204, and a cover insulation layer 205.

The first sensing insulation layer 201 may be an inorganic layer including at least one of a silicon nitride, a silicon oxynitride, or a silicon oxide. Alternatively, the first sensing insulation layer 201 may be an organic layer including an epoxy resin, an acrylic resin, or an imide-based resin. The first sensing insulation layer 201 may have a single-layered structure, or a multi-layered structure in which layers are stacked along the third direction DR3.

Each of the first conductive layer 202 and the second conductive layer 204 may have a single-layered structure, or a multi-layered structure in which layers are stacked along the third direction DR3. In the present embodiment, a metal layer of a single-layered structure may include molybdenum, silver, titanium, copper, aluminum, or an alloy thereof. A conductive layer of a multi-layered structure may include metal layers. In an embodiment, the metal layers may have, for example, a three-layered structure of titanium/aluminum/titanium. The conductive layer of a multi-layered structure may include at least one metal layer and at least one transparent conductive layer.

When the first conductive layer 202 and the second conductive layer 204 include a metal layer, the first conductive layer 202 and the second conductive layer 204 may be opaque. Therefore, the first conductive layer 202 and the second conductive layer 204 may be patterned not to overlap the pixel region PXA but to overlap the non-pixel region NPXA.

At least one of the second sensing insulation layer 203 or the cover insulation layer 205 may include an inorganic film. The inorganic film may include at least one of an aluminum oxide, a titanium oxide, a silicon oxide, a silicon nitride, a silicon oxynitride, a zirconium oxide, or a hafnium oxide.

At least one of the second sensing insulation layer 203 or the cover insulation layer 205 may include an organic film. The organic film may include at least one of an acrylic resin, a methacrylic resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

A portion of the first conductive layer 202 and a portion of the second conductive layer 204 may be connected through a contact-hole CNT defined in the second sensing insulation layer 203.

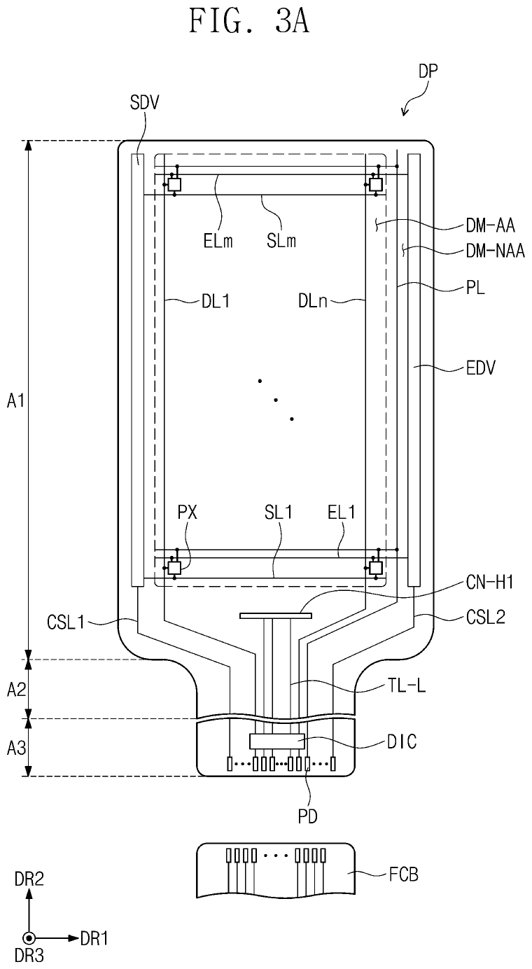

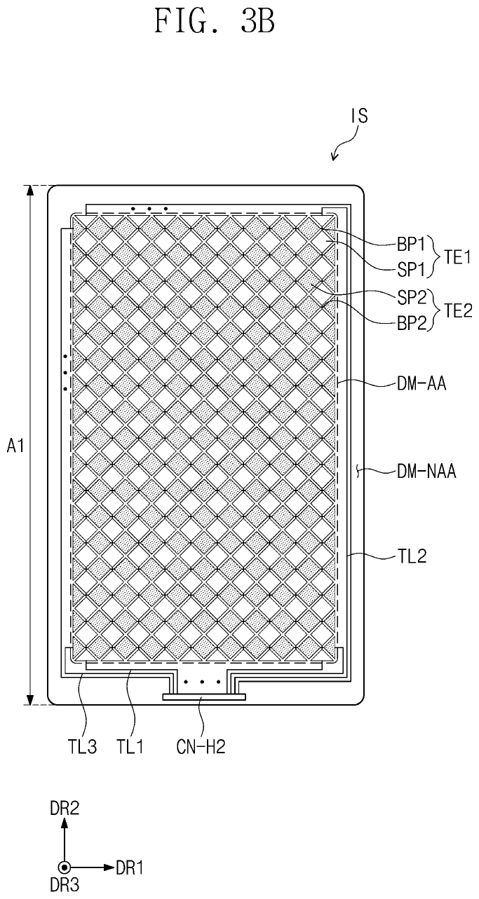

FIG. 3A is a plan view of a display panel according to an embodiment of the invention. FIG. 3B is a plan view of an input sensing layer according to an embodiment of the invention.

Referring to FIG. 3A, the display panel DP according to the invention may be separated into a first region A1, a second region A2, and a third region A3. The first to third regions A1, A2, and A3 of the display panel DP illustrated in FIG. 3A correspond to the first to third regions A1, A2, and A3 of the display module DM described with reference to FIG. 1B, respectively. In the present disclosure, when “a region/portion corresponds to a region/portion,” it means that the region/portion overlaps the region/portion, and the regions/portions are not limited to having the same area.

The display panel DP according to an embodiment may include an active region DM-AA in which a pixel PX is disposed and a peripheral region DM-NAA adjacent thereto. The active region DM-AA and the peripheral region DM-NAA correspond to the active region DM-AA and the peripheral region DM-NAA described with reference to FIG. 1B, respectively.

Therefore, the active region DM-AA corresponds to a region in which the pixel PX is disposed in the first region A1, and the peripheral region DM-NAA includes the remaining first region A1 except for the region in which the pixel PX is disposed, the second region A2, and the third region A3.

The display panel DP may include a scan driver SDV, an emission driver EDV, and a driving circuit unit DIC in the peripheral region DM-NAA. The driving circuit unit DIC may be a data driver.

The display panel DP may include a plurality of pixels PX, a plurality of scan lines SL1 to SLm, a plurality of data lines DLI to DLn, a plurality of light emitting lines ELI to ELm, first and second control lines CSL1 and CSL2, a power line PL, and a plurality of pads PD. Here, m and n are natural numbers. The pixels PX may be connected to the scan lines SL1 to SLm, the data lines DLI to DLn, and the light emitting lines ELI to ELm.

The scan lines SL1 to SLm may be extended in the first direction DR1 and connected to the scan driver SDV. The data lines DLI to DLn are extended in the second direction DR2, and may be connected to the driving circuit unit DIC disposed in the third region A3 via the second region A2 from the first region A1. The light emitting lines ELI to ELm may be extended in the first direction DR1 and be connected to the emission driver EDV.

The power line PL may include a portion extended in the first direction DR1 and a portion extended in the second direction DR2. The portion extended in the first direction DR1 and the portion extended in the second direction DR2 may be disposed on different layers. The portion of the power line PL extended in the second direction DR2 may be extended to the third region A3 via the second region A2 from the first region A1. The power line PL may provide a reference voltage to the pixels PX.

The first control line CSL1 is connected to the scan driver SDV, and may be extended to the third region A3 via the second region A2 from the first region A1. The second control line CSL2 is connected to the emission driver EDV, and may be extended to the third region A3 via the second region A2 from the first region A1.

The pads PD may be disposed adjacent to an end of the third region A3. The driving circuit unit DIC, the power line PL, the first control line CSL1, and the second control line CSL2 may be connected to the pads PD. The flexible circuit board FCB may be disposed on the display panel DP while overlapping an end of the third region A3 in the display panel DP. The flexible circuit board FCB includes pads corresponding to the pads PD, and may be electrically connected to the pads PD through an anisotropic conductive adhesive layer.

The display panel DP according to an embodiment may include a first contact-hole CN-H1 defined in the first region A1. The display panel DP may include extension sensing lines TL-L extended from the first contact-hole CN-H1 to the third region A3 via the first region A1 and the second region A2. The extension sensing lines TL-L may be connected one-to-one to a corresponding sensing line among sensing lines TL1, TL2, and TL3 to be described later.

Although FIG. 3A illustrates that the extension sensing lines TL-L are disposed between the data lines DLI to DLn, the embodiment of the invention is not limited thereto, and the data lines DLI to DLn may be disposed between the extension sensing lines TL-L, in another embodiment and accordingly, the first contact-hole CN-H1 may be provided in plurality with the data lines DLI to DLn interposed therebetween, and is not limited to any one embodiment.

Referring to FIG. 3B, the input sensing layer IS according to an embodiment may include sensing electrodes TE1 and TE2 and the sensing lines TL1, TL2, and TL3. When the input sensing layer IS directly disposed on the display panel DP by a continuous process, the input sensing layer IS may be disposed only in a region overlapping the first region A1 of the display panel DP.

The input sensing layer IS may obtain information on an external input through a change in capacitance between the first sensing electrodes TE1 and the second sensing electrodes TE2. The first sensing electrodes TE1 are arranged along the first direction DR1 and each thereof is extended in the second direction DR2. Each of the first sensing electrodes TE1 may include a first sensing pattern SP1 and a first connection pattern BP1.

The first sensing pattern SP1 is disposed in the active region DM-AA. The first sensing pattern SP1 may have a rhombus shape. However, this is exemplarily illustrated, and the first sensing pattern SP1 may have various shapes, and is not limited to any one embodiment.

The first connection pattern BP1 is disposed in the active region DM-AA. The first connection pattern BP1 may be disposed between adjacent first sensing patterns. The first connection pattern BP1 and the first sensing pattern SP1 may be disposed on different layers from each other and be connected through a contact-hole.

The second sensing electrodes TE2 are arranged along the second direction DR2, and each thereof is extended along the first direction DR1. Each of the second sensing electrodes TE2 may include a second sensing pattern SP2 and a second connection pattern BP2.

The second sensing patterns SP2 may be spaced apart from the first sensing pattern SP1. The first sensing pattern SP1 and the second sensing pattern SP2 may not be in contact with each other, and thus, may transmit and receive independent electrical signals.

The second sensing pattern SP2 may have the same shape as a shape of the first sensing pattern SP1. In an embodiment, for example, the second sensing pattern SP2 may have a rhombic shape. However, this is exemplarily illustrated, and the second sensing pattern SP2 may have various shapes, and is not limited to any one embodiment.

The second connection pattern BP2 may be disposed between adjacent second sensing patterns. For convenience of description, the second sensing electrode TE2 has been described by being separated into the second sensing pattern SP2 and the second connection pattern BP2, but the second sensing electrode TE2 may be provided as substantially a single pattern.

According to an embodiment, the first connection pattern BP1 may correspond to the first conductive layer 202 described with reference to FIG. 2. The first sensing pattern SP1, the second sensing pattern SP2, and the second connection pattern BP2 may correspond to the second conductive layer 204 described with reference to FIG. 2. That is, the second sensing electrode TE2 and the first sensing pattern SP1 may be disposed on the same layer, wherein the first sensing pattern SP1 and the second sensing electrode TE2 may be provided as a plurality of mesh lines extended in a diagonal direction of each of the first direction DR1 and the second direction DR2.

The sensing lines TL1, TL2, and TL3 are disposed in the peripheral region DM-NAA. The sensing lines TL1, TL2, and T3 may include first sensing lines TL1, second sensing lines TL2, and third sensing lines TL3.

The first sensing lines TL1 are connected to the first sensing electrodes TE1, respectively. In the present embodiment, the first sensing lines TL1 are connected to lower ends of opposite ends of the first sensing electrodes TE1, respectively. The second sensing lines TL2 are connected to upper ends of opposite ends of the first sensing electrodes TE1, respectively. According to the invention, the first sensing electrodes TE1 may be connected to each of the first sensing lines TL1 and the second sensing lines TL2. Accordingly, sensitivity according to a region may be uniformly maintained with respect to the first sensing electrodes TE1 which are relatively long compared to the second sensing electrodes TE2.

This is exemplarily illustrated, and in the input sensing layer IS according to an embodiment of the invention, the second sensing lines TL2 may be omitted, and are not limited to any one embodiment.

The third sensing lines TL3 are connected to certain ends of the second sensing electrodes TE2, respectively. In the present embodiment, the third sensing lines TL3 are connected to left ends of opposite ends of the second sensing electrodes TE2, respectively.

The input sensing layer IS may include a second contact-hole CN-H2 overlapping the peripheral region DM-NAA. The second contact hole CN-H2 may overlap the first contact-hole CN-H1 of the display panel DP. The sensing lines TL1, TL2, and TL3 may be connected to corresponding extension sensing lines TL-L through the second contact-hole CN-H2 defined in the input sensing layer IS and the first contact-hole CN-H1 defined in the display panel DP. Accordingly, the sensing electrodes TE1 and TE2 may be electrically connected to the flexible circuit board FCB.

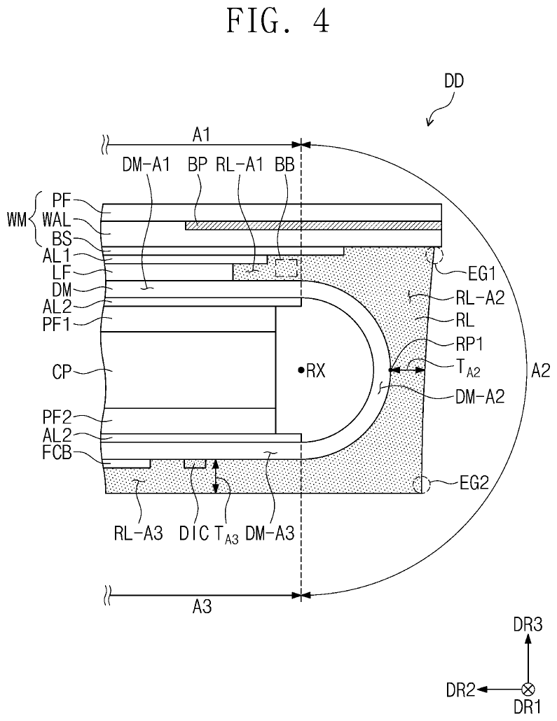

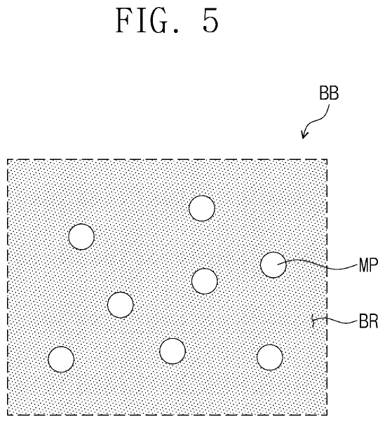

FIG. 4 is a cross-sectional view showing a display device according to an embodiment of the invention. FIG. 5 is a view of an enlarged resin layer of an embodiment of the invention. FIG. 5 is an enlarged view of a portion corresponding to the area BB illustrated in FIG. 4.

Referring FIG. 4, a display device DD of an embodiment may include a display module DM, a driving circuit unit DIC disposed on the display module DM, and a resin layer RL. The display device DD may further include at least one of a window WM, an optical film LF, a bending protection layer BFL, a cover film CIC, a cover panel CP, or an adhesive layer AL1.

According to an embodiment, the window WM may include a base substrate BS, a window protection layer PF disposed on the base substrate BS, and a bezel pattern BP disposed on a lower surface of the window protection layer PF. The window WM may further include a window adhesive layer WAL for coupling the window protection layer PF and the base substrate BS.

In an embodiment, the display module DM may include a first flat portion DM-A1, a second flat portion DM-A3, and a bending portion DM-A2. The first flat portion DM-A1 may be a portion adjacent to the window WM. The second flat portion DM-A3 may be a portion facing the first flat portion DM-A1. The bending portion DM-A2 may be a portion disposed between the first flat portion DM-A1 and the second flat portion DM-A3. The bending portion DM-A2 may be a portion bent to a predetermined radius of curvature with respect to a bending axis RX. That is, the display module DM may have a shape in which the bending portion DM-A2 is bent with respect to the bending axis RX, and the first flat portion DM-A1 and the second flat portion DM-A3 face each other.

In an embodiment, the first flat portion DM-A1 may correspond to the first region A1 of the display module DM (see FIG. 1B). The second flat portion DM-A3 may correspond to the third region A3 of the display module DM (see FIG. 1B). The bending portion DM-A2 may correspond to the second region A2 of the display module DM (see FIG. 1B).

The driving circuit unit DIC may be disposed on the second flat portion DM-A3. The driving circuit unit DIC may be directly disposed on the display module DM.

In an embodiment, the resin layer RL may be disposed on the display module DM. The resin layer RL may include a first resin flat portion RL-A1 disposed on the first flat portion DM-A1, and a second resin flat portion RL-A3 disposed on the second flat portion DM-A3, and a resin bending portion RL-A2 disposed on the bending portion DM-A2. The resin layer RL may be provided as a single layer. That is, the resin layer RL may be a layer formed with one material in one process.

The resin layer RL may cover at least a portion of the first flat portion DM-A1 of the display module DM, the bending portion DM-A2, and at least a portion of the second flat portion DM-A3. The resin layer RL may cover the driving circuit unit DIC. Accordingly, the resin layer RL of an embodiment may prevent the breakage of the bending portion DM-A2 of the display module DM and the driving circuit unit DIC. As a result, the display device DD of an embodiment may exhibit excellent durability by including the resin layer RL.

The resin layer RL may include a polymer resin. In an embodiment, for example, the resin layer RL may include at least one of an acrylic resin, an epoxy-based resin, a silicon-based resin, a pyrrole-based resin, a furan-based resin, a thiophene-based resin, an aniline-based resin, or poly(3,4-ethylenedioxythiophene (“PEDOT”).

At 25° C., the shear modulus of the resin layer RL may be about 1 megapascal (MPa) to about 1000 MPa. When the shear modulus of the resin layer RL is less than about 1 MPa, there is a limitation in preventing, by the resin layer RL, the breakage of the bending portion DM-A2 of the display module DM and the driving circuit portion DIC. The display device DD of an embodiment includes the resin layer RL satisfying a shear modulus of about 1 MPa to about 1000 MPa at 25° C., and thus may prevent the breakage of the bending portion DM-A2 of the display module DM and the driving circuit unit DIC from an external impact, and accordingly, the display device DD may exhibit excellent durability.

The resin layer RL may include a conductive polymer, or may include a conductive filler. Accordingly, the resin layer RL may exhibit electrical conductivity. In an embodiment, for example, the resin layer RL may have an electrical conductivity of about 100 Siemens per square centimeter (S/cm²) or greater. The resin layer RL may perform a shielding function. When the resin layer RL has electrical conductivity, static electricity may be shielded. As a result, the resin layer RL may prevent damage to the display module DM and the driving circuit unit DIC from external static electricity.

In an embodiment, a thickness T_{A3} of the second resin flat portion RL-A3 may be about 50 micrometers (μm) to about 1000 μm. The thickness T_{A3} of the second resin flat portion RL-A3 refers to a thickness in the third direction DR3 with respect to one surface of the second flat portion DM-A3 as shown in FIG. 4. The thickness T_{A3} of the second resin flat portion RL-A3 may refer to a thickness of a part of the second resin flat portion RL-A3 not overlapping the driving circuit unit DIC. Since the display device DD of an embodiment includes the resin layer RL in which the thickness T_{A3} of the second resin flat portion RL-A3 is about 50 μm or greater, the driving circuit unit DIC and the display module DM may be protected from an external impact.

A thickness T_{A2} of the resin bending portion RL-A2 may be about 150 μm to about 3000 μm. The thickness T_{A2} of the resin bending portion RL-A2 refers to a thickness measured from a first reference point RP1 in the second direction DR2 with respect to the bending portion DM-A2 as shown in FIG. 4. The first reference point RP1 may be the rightmost point of the bending portion DM-A2. In an embodiment, when the thickness T_{A2} of the resin bending portion RL-A2 is less than about 150 μm, there is a limitation in protecting the bending portion DM-A2 from an external impact. In addition, when the thickness T_{A2} of the resin bending portion RL-A2 is greater than about 3000 μm, there is a problem in that the resin bending portion RL-A2 is exposed to the outside of the window WM in the third direction DR3. Since the display device DD includes the resin layer RL in which the thickness T_{A2} of the bending portion RL-A2 satisfies the range of about 150 μm to about 3000 μm, the resin layer RL may not be exposed to the outside of the window WM, and the bending portion DM-A2 may be protected from an external impact.

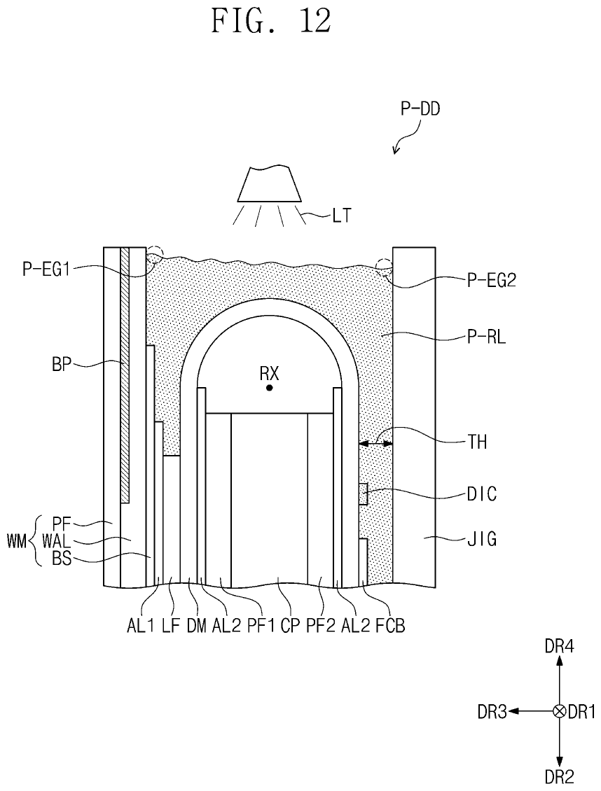

In the third direction DR3, a first edge EG1 of the resin bending portion RL-A2 may not be parallel to a second edge EG2 of the resin bending portion RL-A2. The first edge EG1 may be in contact with the window WM. The second edge EG2 is extended from the first edge EG1, and may be spaced apart from the window WM. The second edge EG2 may be in contact with a jig (see FIG. 12) in a method for manufacturing a display device to be described later. The first edge EG1 may be disposed further outside than the second edge EG2. Due to surface tension between the resin layer RL and the window WM, the first edge EG1 may be disposed relatively outside.

The display device DD of an embodiment may further include the window WM disposed on the display module DM and an adhesive layer AL1 disposed between the window WM and the display module DM. The window WM may be disposed on the first flat portion DM-A1. The resin layer RL may fill a groove defined by the display module DM, the window WM, and one side surface of an exposed part of the optical film LF. The resin layer RL may be in contact with the optical film LF. The resin layer RL may be in contact with the window WM. The resin layer RL may be in contact with the first flat portion DM-A1. The resin layer RL may be disposed further inside than the window WM.

Referring to FIG. 5, the resin layer RL of an embodiment may further include a base portion BR, and metal particles MP dispersed inside the base portion BR. Accordingly, the resin layer RL of an embodiment may exhibit electrical conductivity. The electrical conductivity of the resin layer RL of an embodiment may be about 100 S/cm² or greater. As a result, the resin layer RL of an embodiment may exhibit shielding properties, thereby preventing damage to the driving circuit unit DIC and the display module DM from external static electricity.

The base portion BR may include at least one of an acrylic resin, an epoxy-based resin, a silicon-based resin, a pyrrole-based resin, a furan-based resin, a thiophene-based resin, an aniline-based resin, or PEDOT. The metal particle MP may include at least one of Cu or Al.

In FIG. 5, the metal particle MP is illustrated in a spherical shape, but the shape and size of the metal particle MP are not limited. In an embodiment, for example, the metal particle MP may have a rod shape or a needle shape.

In an embodiment, the resin layer RL may include about 0.01 volume percent (vol %) to about 85.00 vol % of the metal particles MP based on the total volume of the resin layer RL. When the resin layer RL of an embodiment includes less than about 0.01 vol % of the metal particles MP based on the total volume of the resin layer RL, low electrical conductivity is exhibited, and thus, there is a limitation in performing a shielding function. When the resin layer RL of an embodiment includes greater than about 85.00 vol % of the metal particles MP based on the total volume of the resin layer RL, there is a problem in that it is difficult to maintain the shape of the resin layer RL.

Referring back to FIG. 4, the display device DD of an embodiment may include lower protection films PF1 and PF2 disposed in a lower portion of the display module DM. The lower protection films PF1 and PF2 may include a first protection film PF1 disposed in a lower portion of the first region A1 and a second protection film PF2 disposed in a lower portion of the third region A3. Since the lower protection films PF1 and PF2 are not disposed in a lower portion of the second region A2, the bending of the display module DM may be facilitated.

In a lower portion of the first protection film PF1, the cover panel CP may be disposed. The first protection film PF1 and the cover panel CP may be coupled by a second adhesive layer AL2. As illustrated in FIG. 4, since the second region A2 of the display module DM is bent, the second protection film PF2 may be coupled to the cover panel CP. The second protection film PF2 and the cover panel CP may be coupled by a third adhesive layer AL3. The cover panel CP may be disposed between the first protection film PF1 and the second protection film PF2 after the second region A2 of the display module DM is bent, and support the bent display module DM.

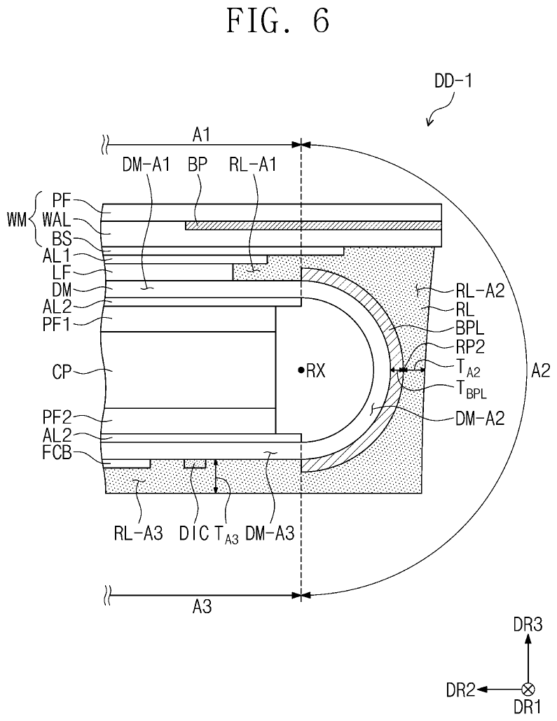

Hereinafter, a display device according to an embodiment will be described with reference to FIG. 6 to FIG. 9. In the description of the display device of an embodiment illustrated in FIG. 6 to FIG. 9, the same contents as those described with reference to FIG. 1 to FIG. 5 will not be described again, and instead, differences will be mainly described.

The display device illustrated in FIG. 6 is different from the display device described with reference to FIG. 1 to FIG. 5 in that the display device further includes a bending protection layer BPL.

FIG. 6 is a cross-sectional view showing a portion of a display device of another embodiment of the invention.

Referring to FIG. 6, a display device DD-1 of an embodiment may further include the bending protection layer BPL disposed on the bending portion DM-A2. The bending protection layer BPL may not overlap each of a first flat portion DM-A1 and a second flat portion DM-A3. The bending protection layer BPL may be a component for preventing damage to the bending portion DM-A2 in a process of bending the display module DM to form the bending portion DM-A2.

The bending protection layer BPL may include a polymer resin. In an embodiment, for example, the bending protection layer BPL may include at least one of an acrylic resin, an epoxy-based resin, or a silicon-based resin. The material of the bending protection layer BPL may be the same as, or different from, the material of the resin layer RL.

The bending protection layer BPL may be a layer separated from the resin layer RL. The bending protection layer BPL and the resin layer RL may be components formed in different processes. A thickness T_{BPL} of the bending protection layer BPL may be smaller than a thickness T_{A2} of a resin bending portion RL-A2. The comparison between the thickness T_{BPL} of the bending protection layer BPL and the thickness T_{A2} of the resin bending portion RL-A2 is based on measurements taken at the same point. In an embodiment, for example, in FIG. 6, the thickness T_{BPL} of the bending protection layer BPL and the thickness T_{A2} of the resin bending portion RL-A2 are measured as distances from a second reference point RP2 in the second direction DR2 and a direction opposite to the second direction DR2, respectively. The second reference point RP2 may be the rightmost point of the bending protection layer BPL.

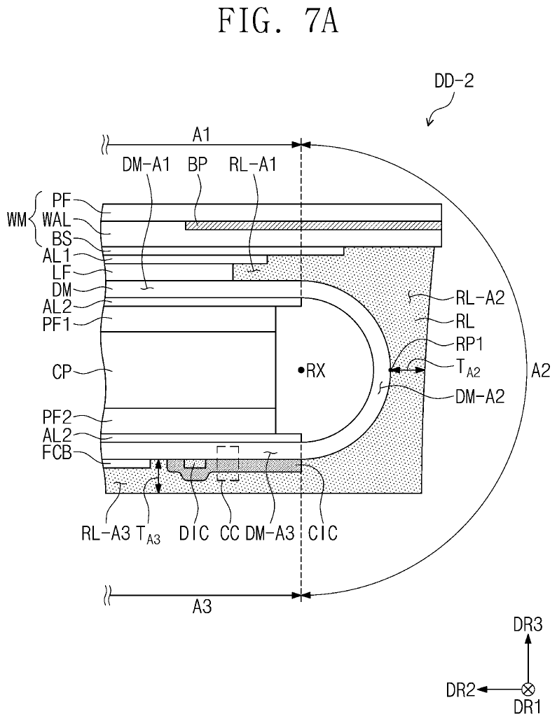

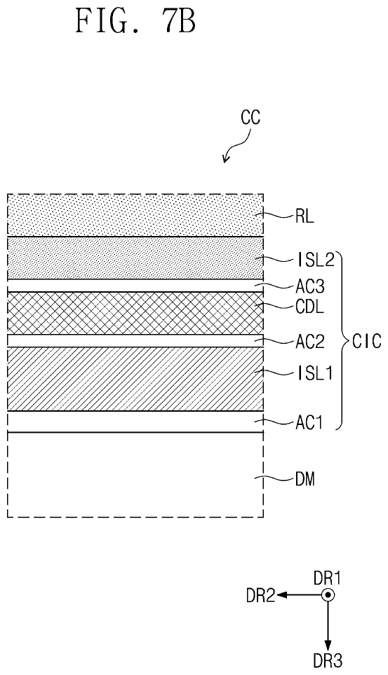

A display device illustrated in FIG. 7A is different from the display device described with reference to FIG. 1 to FIG. 5 in that the display device further includes a cover film CIC.

FIG. 7A is a cross-sectional view showing a portion of a display device of still another embodiment of the invention. FIG. 7B is a view showing a cover film of an embodiment of the invention in detail. FIG. 7B is an enlarged view of a portion corresponding to the area CC illustrated in FIG. 7A.

A display device DD-2 of an embodiment may include the cover film CIC disposed on a second flat portion DM-A3. The cover film CIC may cover a driving circuit unit DIC. The cover film CIC may cover at least a portion of the second flat portion DM-A3. The cover film CIC may not overlap a bending portion DM-A2.

The cover film CIC may cover the driving circuit unit DIC and cover at least a portion of a display module DM, thereby protecting the driving circuit unit DIC and the display module DM from an external impact.

The cover film CIC may have a predetermined thickness. When the thickness of the cover film CIC is excessively reduced, the performance of protecting the second flat portion DM-A3 of the display module DM may be reduced. When the thickness of the cover film CIC is excessively increased, a phenomenon in which the cover film CIC is lifted from the display module DM may occur. Therefore, the cover film CIC may have various thicknesses within a range which allows the lifting phenomenon to be prevented and the protection performance to be effectively improved.

A first cover insulation layer ISL1 may be disposed on the display module DM. The first cover insulation layer ISL1 and the display module DM may be coupled by a first cover adhesive layer AC1. According to an embodiment, the first cover insulation layer ISL1 may include an insulation material. In an embodiment, for example, the first insulation layer ISL1 may include a polymer material. The polymer material according to an embodiment may include at least one of polyethylene terephthalate (“PET”) or a foam. The first cover insulation layer ISL1 may include polyethylene terephthalate (PET).

According to an embodiment, the first cover insulation layer ISL1 includes a metal material having high flexibility, and the first cover adhesive layer AC1 may include an insulating adhesive. In an embodiment, for example, the first cover insulation layer ISL1 may include copper (Cu). When the first cover insulation layer ISL1 includes copper (Cu), the thickness required to have a predetermined modulus value is less than a modulus value of a polymer material. In addition, a force to restore the first cover insulation layer ISL1 to a state before being bent after being bent together with the second region A2 of the display module DM is small. Accordingly, it is possible to prevent a phenomenon that the cover film CIC is lifted from the display module DM.

However, the embodiment of the invention is not limited thereto, and the first cover insulation layer ISL1 may include an adhesive insulation material in another embodiment. At this time, the first cover adhesive layer AC1 may be omitted.

A middle layer CDL may be disposed on the first cover insulation layer ISL1. The middle layer CDL and the first cover insulation layer ISL1 may be coupled by a second cover adhesive layer AC2.

The middle layer CDL may include a conductive material. In an embodiment, for example, the middle layer CDL may include any one of a metal material and a conductive fiber. A conductive fiber according to an embodiment may include a non-woven fabric. The middle layer CDL may shield static electricity by being disposed between the first cover insulation layer ISL1 and the second cover insulation layer ISL2. Therefore, the cover film CIC may prevent the display module DM from being damaged due to external static electricity.

The second cover adhesive layer AC2 may include a conductive adhesive material. In an embodiment, for example, the second cover adhesive layer AC2 may be a film formed by dispersing metal particles inside a synthetic resin. The metal particles may be made of gold, silver, platinum, nickel, copper, carbon, or the like. The synthetic resin may include a material such as epoxy, silicon, polyimide, polyurethane, or the like.

The second cover insulation layer ISL2 may be disposed on the middle layer CDL. The second cover insulation layer ISL2 and the middle layer CDL may be coupled by a third cover adhesive layer AC3.

The second cover insulation layer ISL2 may include an insulation material. In an embodiment, the second cover insulation layer ISL2 may include an organic material, and may include, for example, polyethylene terephthalate (PET). According to an embodiment, the second cover insulation layer ISL2 may have a black color, and may perform a light blocking function.

The stacking structure of the cover film CIC illustrated in FIG. 7B is merely an example, and the embodiment of the invention is not limited thereto, and any one layer may be omitted in another embodiment.

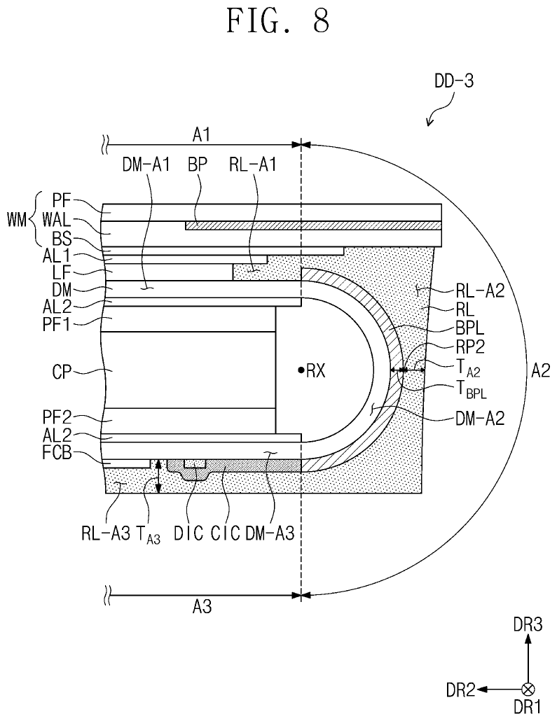

A display device illustrated in FIG. 8 is different from the display device described with reference to FIG. 1 to FIG. 5 in that the display device further includes a bending protection layer BPL and a cover film CIC.

FIG. 8 is a cross-sectional view showing a portion of a display device of yet another embodiment of the invention. Referring to FIG. 8, a display device DD-3 of an embodiment may include a cover film CIC and the bending protection layer BPL. The resin layer RL may cover both the cover film CIC and the bending protection layer BPL. A second resin flat portion RL-A3 may cover the cover film CIC. A resin bending portion RL-A2 may cover the bending protection layer BPL.

The same contents as those for the bending protection layer BPL described with reference to FIG. 6 may be applied to the bending protection layer BPL illustrated in FIG. 8. The same contents as those for the cover film CIC described with reference to FIG. 7 may be applied to the cover film CIC illustrated in FIG. 8.

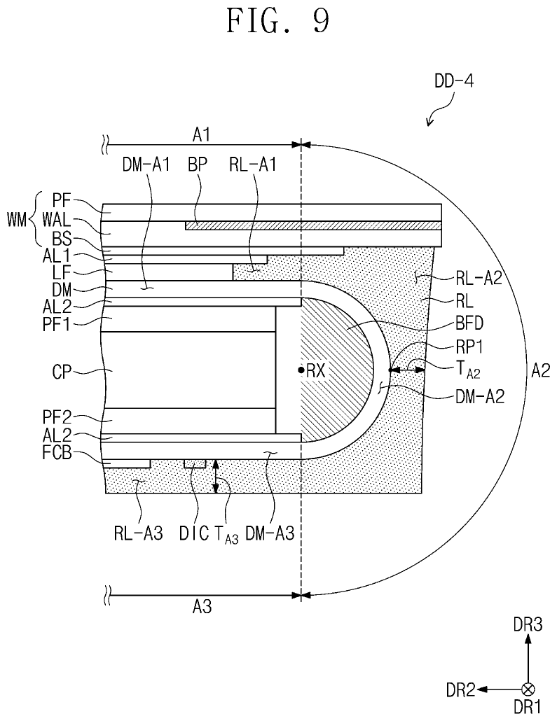

A display device illustrated in FIG. 9 is different from the display device described with reference to FIG. 1 to FIG. 5 in that the display device further includes an internal bending protection layer BFD.

FIG. 9 is a cross-sectional view showing a portion of a display device of another embodiment of the invention. Referring to FIG. 9, a display device DD-4 of an embodiment may include the internal bending protection layer BFD. The internal bending protection layer BFD may be directly disposed on a lower surface of a bending portion DM-A2. The internal bending protection layer BFD may fill at least a portion of a space defined by an exposed part of the cover panel CP, a first flat portion DM-A1, a second flat portion DM-A3, and the bending portion DM-A2. The internal bending protection layer BFD may perform a function of reducing stress generated as a display module DM is bent. The internal bending protection layer BFD may be referred to as a “panel inner protection layer”.

The internal bending protection layer BFD may overlap at least a portion of the bending portion DM-A2. The internal bending protection layer BFD may not overlap each of the first flat portion DM-A1 and the second flat portion DM-A3.

The internal bending protection layer BFD may include at least one of an acrylic resin, an epoxy-based resin, or a silicon-based resin. In an embodiment, for example, the internal bending protection layer BFD may include two or more different types of resins among an acrylic resin, an epoxy-based resin, and a silicon-based resin, or one type of a resin thereof.

Although not illustrated, a display device of an embodiment may include all of the internal bending protection layer BFD, the cover film CIC, and the bending protection layer BPL.

Hereinafter, referring to FIG. 10A to FIG. 12, a method for manufacturing a display device of an embodiment will be described. Structural features described with reference to FIG. 1 to FIG. 5 will not be described again, and features of the manufacturing method will be described.

FIG. 10A is a view showing a preliminary display device P-DD before bending. FIG. 10B is a view showing the preliminary display device P-DD after bending.

Referring to FIG. 10A and FIG. 10B, in the manufacturing method of a display device, the preliminary display device P-DD before bending may not include the resin layer RL (see FIG. 4). That is, in the preliminary display device P-DD, a display module DM may be bent without the resin layer RL (see FIG. 4) formed on the display module DM. Although not illustrated, when the preliminary display device P-DD of an embodiment includes the bending protection layer BPL (see FIG. 8) illustrated in FIG. 8, the bending protection layer BPL (FIG. 8) may be formed on the display module DM, and then the display module DM may be bent.

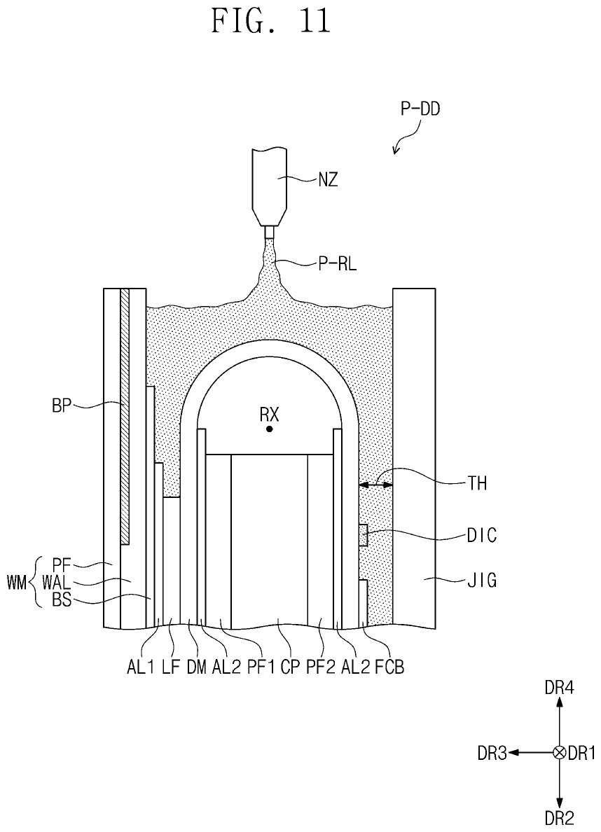

FIG. 11 is a view schematically showing a process of applying a preliminary resin layer P-RL on the preliminary display device P-DD after bending.

Referring to FIG. 11, the method for manufacturing a display device of an embodiment may include a step of applying the preliminary resin layer P-RL on the preliminary display device P-DD. The step of applying the preliminary resin layer P-RL may be a step of applying the preliminary resin layer P-RL by using a nozzle NZ at one side of the preliminary display device P-DD. With respect to the preliminary display device P-DD, the nozzle NZ positioned in a fourth direction DR4, which is an opposite direction to the second direction DR2, may apply the preliminary resin layer P-RL in a direction of the preliminary display device P-DD. The second direction DR2 may be an inward direction of the preliminary display device P-DD, and the fourth direction DR4 may be an outward direction of the preliminary display device P-DD.

Specifically, the preliminary resin layer P-RL may be applied on a groove formed by a window WM, a display module DM, and an adhesive layer AL1, and a groove formed by a jig JIG and the display module DM. By adjusting a gap TH between the jig JIG and the display module DM, it is possible to adjust the thickness T_{A3} (see FIG. 4) of the second resin flat portion RL-A3 (see FIG. 4). In an embodiment, for example, the gap TH between the jig JIG and the display module DM may be about 50 μm to about 1000 μm.

FIG. 12 is a view schematically illustrating a step of irradiating the preliminary resin layer P-RL with light LT.

Referring to FIG. 12, the method for manufacturing a display device of an embodiment may include a step of irradiating the preliminary resin layer P-RL with the light LT. The light LT may be ultraviolet light. By irradiating the preliminary resin layer P-RL with the light LT, it is possible to form a resin layer RL. As a result, the display device DD illustrated in FIG. 4 may be manufactured.

In the third direction DR3, a third edge P-EG1 of the preliminary resin layer P-RL may not be parallel to a fourth edge P-EG2 of the preliminary resin layer P-RL. The third edge P-EG1 of the preliminary resin layer P-RL may be in contact with a window WM. The fourth edge P-EG2 of the preliminary resin layer P-RL is extended from the third edge P-EG1 of the preliminary resin layer P-RL, and may be in contact with a jig JIG. Due to the surface tension between the preliminary resin layer P-RL and the window WM, the third edge P-EG1 of the preliminary resin layer P-RL may be disposed relatively outside. Accordingly, in the resin layer RL (see FIG. 4) formed from the preliminary resin layer P-RL, as described with reference to FIG. 4, the first edge EG1 of the resin layer RL may be disposed further outside than the second edge EG2 of the resin layer RL.

A display panel of an embodiment includes a bending portion of a display panel, and a resin layer which covers a driving circuit unit disposed on the display panel. The resin layer may prevent the breakage of the bending portion of the display panel and the driving circuit unit. Accordingly, the display device of an embodiment may exhibit excellent durability.

Although the invention has been described with reference to a preferred embodiment of the invention, it will be understood by those skilled in the art that various changes in form and details may be made therein without departing from the spirit and scope of the invention as set forth in the following claims. Accordingly, the technical scope of the invention is not intended to be limited to the contents set forth in the detailed description of the specification, but is intended to be defined by the appended claims.

What is claimed is:

1. A display device comprising:
a display module including a first flat portion, a second flat portion facing the first flat portion, and a bending portion disposed between the first flat portion and the second flat portion and having a predetermined radius of curvature;
a driving circuit unit disposed on the second flat portion;
a bending protection layer disposed on the bending portion, and not overlapping the first flat portion and the second flat portion;
a cover film disposed on the second flat portion, and covering the driving circuit unit; and
a resin layer including a first resin flat portion disposed on at least a portion of the first flat portion, a second resin flat portion disposed on the second flat portion and covering the cover film, and a resin bending portion disposed on the bending portion and covering the bending protection layer.

2. The display device of claim 1, wherein a thickness of a part of the second resin flat portion not overlapping the driving circuit unit is about 50 micrometers (μm) to about 1000 μm.

3. The display device of claim 1, wherein a thickness of the resin bending portion is greater than a thickness of the bending protection layer.

4. The display device of claim 3, wherein the thickness of the resin bending portion is about 150 μm to about 3000 μm.

5. The display device of claim 1, wherein an electrical conductivity of the resin layer is about 100 Siemens per square centimeter (S/cm²) or greater.

6. The display device of claim 1, wherein the resin layer comprises at least one of an acrylic resin, an epoxy-based resin, a silicon-based resin, a pyrrole-based resin, a furan-based resin, a thiophene-based resin, an aniline-based resin, or poly(3,4-ethylenedioxythiophene (PEDOT).

7. The display device of claim 1, wherein the resin layer comprises a base portion, and metal particles dispersed inside the base portion, wherein the metal particles include at least one of copper (Cu) or aluminium (A1).

8. The display device of claim 7, wherein the resin layer comprises about 0.01 volume percent (vol %) to about 85.00 vol % of the metal particles based on a total volume of the resin layer.

9. The display device of claim 1, wherein a shear modulus of the resin layer at 25° C. is about 1 megapascal (MPa) to about 1000 MPa.

10. The display device of claim 1, further comprising a window disposed on the display module, wherein the window is directly disposed on the first resin flat portion.

11. The display device of claim 1, wherein the resin layer is provided as a single layer.

12. The display device of claim 1, wherein the cover film comprises:
a first cover insulation layer;
a middle layer disposed on the first cover insulation layer; and
a second cover insulation layer disposed on the middle layer.

13. The display device of claim 1, wherein the driving circuit unit is directly disposed on the second flat portion.

14. The display device of claim 1, further comprising:
a cover panel disposed between the first flat portion and the second flat portion; and
a panel inner protection layer filling a space defined by an exposed part of the cover panel, the first flat portion, the second flat portion, and the bending portion.

15. A display device comprising:
a display module including a first flat portion, a second flat portion facing the first flat portion, and a bending portion disposed between the first flat portion and the second flat portion and having a predetermined radius of curvature;
a window disposed on the first flat portion;
an adhesive layer disposed between the display module and the window;
a driving circuit unit disposed on the second flat portion; and
a resin layer including a first resin flat portion filling a groove defined by the first flat portion, the window, and an exposed part of the adhesive layer, a second resin flat portion disposed on the second flat portion and covering the driving circuit unit, and a resin bending portion disposed on the bending portion.

16. The display device of claim 15, wherein the resin layer is provided as a single layer.

17. The display device of claim 15, wherein the window is directly disposed on the first resin flat portion.

18. The display device of claim 15, wherein an electrical conductivity of the resin layer is about 100 S/cm² or greater.

19. The display device of claim 15, wherein the resin layer comprises a base portion, and metal particles dispersed inside the base portion, wherein the metal particles include at least one of Cu or Al.

20. The display device of claim 15, wherein a shear modulus of the resin layer at 25° C. is about 1 MPa to about 1000 MPa.
